(19) United States
(12) Patent Application Publication
(10) Pub. No.: US 2021/0193488 A1
(43) Pub. Date: Jun. 24, 2021

(54) ANNEALING DEVICES INCLUDING THERMAL HEATERS

(71) Applicant: HEWLETT-PACKARD DEVELOPMENT COMPANY, L.P., Spring, TX (US)

(72) Inventors: Robert IONESCU, Palo Alto, CA (US); Ning GE, Palo Alto, CA (US); Jarrid WITTKOPF, Palo Alto, CA (US); Helen A HOLDER, Palo Alto, CA (US)

(73) Assignee: Hewlett-Packard Development Company, L.P., Spring, TX (US)

(21) Appl. No.: 17/047,023

(22) PCT Filed: Jul. 11, 2018
(86) PCT No.: PCT/US2018/041680

§ 371 Date: Oct. 12, 2020

(51) Int. Cl. H01L 21/67; H05B 3/22; H01L 21/324

(52) U.S. Cl. CPC H01L 21/67115; B81C 2201/0116; H01L 21/324; H05B 3/22

(57) ABSTRACT

An annealing device may include an array of thermal heaters, each thermal heater comprising a resistive element formed into a cavity and wherein each of the thermal heaters within the array of thermal heaters are selectively activated to anneal an annealable material deposited into the cavities.

### BACKGROUND

Annealing of materials used to form microelectromechanical system (MEM) devices such as semiconductor devices may be formed using a number of methods. In an example, these methods may include an annealing process that is conducted in an oven or chemical vapor deposition (CVD) system. Formation of the MEM devices may provide for a variety of integrated circuits present in a number of electrical devices manufactured today.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a diagram of an annealing device according to an example of the principles described herein.

FIG. 2 is a flowchart showing a method of annealing an annealable material according to an example of the principles describe herein,

FIG. 3 is a block diagram of an annealing system according to an example of the principles described herein.

FIG. 4 is a side view of a thermal resistive element according to an example of the principles described herein.

FIG. 5 is a top view of an array of thermal resistive elements according to an example of the principles described herein.

FIGS. 6A-6C are a number of diagrams showing an annealing process according to an example of the principles described herein.

FIGS. 7A and 7B are a number of diagrams showing an annealing process according to an example of the principles described herein.

Throughout the drawings, identical reference numbers designate similar; but not necessarily identical, elements. The figures are not necessarily to scale, and the size of some parts may be exaggerated to more clearly illustrate the example shown. Moreover, the drawings provide examples and/or implementations consistent with the description; however; the description is not limited to the examples and/or implementations provided in the drawings.

### DETAILED DESCRIPTION

In manufacturing MEM devices such as a semiconductor, the materials used to form the MEM devices may be subjected to an annealing process. These materials may be annealed in; for example; an oven or CVD system. These systems use long ramping and heating times due to the large volume of material that is heated. Complex devices and structures such as the MEM devices cannot be heated in a CVD because they will be destroyed. A localized heating could be used, instead, in order to generate these relatively more advanced structures. For example, creating heterostructures such as these MEM devices is usually done by transfer of films generated through multiple CVD processes.

The present specification describes a thermally controlled substrate that includes an array of thermal heaters. With this thermally controlled substrate the MEM devices can be built using relatively less processes and can accommodate thermally sensitive materials along with high temperature annealing.

The present specification describes an annealing device that includes an array of thermal heaters, each thermal heater comprising a resistive element formed into a cavity and wherein each of the thermal heaters within the array of thermal heaters are selectively activated to anneal an annealable material deposited into the cavities.

The present specification further describes a method of annealing an annealable material that includes, with a deposition device, depositing an amount of annealable material into a cavity of a thermal resistive element of an array of thermal resistive elements and selectively activating the thermal resistive element to anneal the annealable material.

The present specification also describes an annealing system that includes a material deposition device to selectively deposit an amount of annealable material and a two-dimensional array of thermal resistive elements, each thermal resistive element of the two-dimensional array of thermal resistive elements comprising a cavity to receive an amount of annealable material.

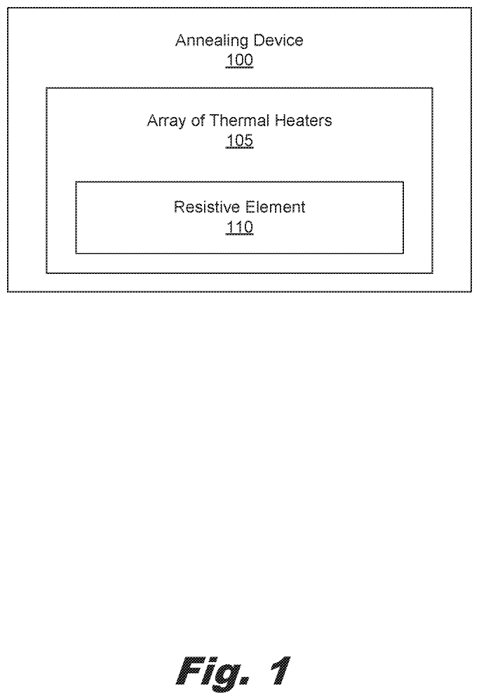

Turning now to the figures, FIG. 1 is a diagram of an annealing device (100) according to an example of the principles described herein. In any examples presented herein, the annealing device (100) may include an array of thermal heaters (105) with each of the thermal heaters including a resistive element (110).

In any example presented herein, the array of thermal heaters (105) may be formed into a two-dimensional array. In this example, each of the thermal heaters of the array of thermal heaters (105) has a side that contacts another thermal heater. This two-dimensional (2D) arrangement allows a number of MEM devices to be formed along side other MEM devices so as to form, in an example, a 2D plane of MEM devices.

In any example presented herein, the array of thermal heaters (105) may be formed into a three-dimensional (3D) array with some thermal heaters of the array of thermal heaters (105) being above or below other thermal heaters. Indeed, other examples exist where individual thermal heaters of the array of thermal heaters (105) are not on the same plane as that formed by a 2D plane. Although the present specification is describing an array of thermal heaters (105) that are formed into a 2D plane, the present specification contemplates that the same processes described herein may be equally applied to a 3D arrangement of the array of thermal heaters (105).

The thermal heaters of the array of thermal heaters (105) may each include a layer of resistive metal and a passivation layer. In this example, the resistive layer acts as a resistive element (110). The resistive element (110) may selectively receive an electrical current causing the resistive layer to be heated. The heating may cause an annealable material in contact with or influenced by each of the resistive elements (110) to be annealed.

In an example, the passivation layer of the thermal heater may not be present. In any example, however, the passivation layer may be included between the resistive element (110) and the annealable material. In this example, the passivation layer may prevent any chemical and/or other transformative reaction between the resistive element (110) and the annealable material.

In an example, each of the thermal heaters of the array of thermal heaters (105) may include a cavity. The cavity may be of any form that receives an amount of annealable material therein to be annealed. In an example, the cavity may include a planar surface with walls sufficient to maintain an amount of annealable material therein. In an example, the walls may receive the amount of annealable material in the cavity allowing the annealable material to take the volumetric shape of the cavity. In some examples, a number of different types of annealable materials may be successively deposited into and annealed within the cavity. In any example presented herein, other types of material may be deposited within the cavity of the thermal heaters such as a photoresist to control the placement and annealing of the annealable material within the cavity.

The resistive elements (110) of the annealing device (100) may be formed of any type of resistive metals. Examples of the resistive metals may include alloys of tantalum, aluminum, tungsten, tin, copper, titanium and silicon such as TaAl, WSiN, TaSiN, TaN, TiN, Ta₂Os, AlCu or the like, or combinations thereof.

During operation of the annealing device (100), each of the resistive elements (110) of the array of thermal heaters (105) may be individually activated. Activation causes each of the resistive elements (110) to heat up and anneal an annealable substance placed in the cavity. The annealing device (100) may be communicatively coupled to a processing device that, according to execution of computer readable program code, causes each of the individual thermal heaters (105) to be selectively activated in order to anneal the annealable material deposited in the cavities. The processor may be any type of processing device and the present specification contemplates that the processor includes any device that can access computer readable program code and execute that code.

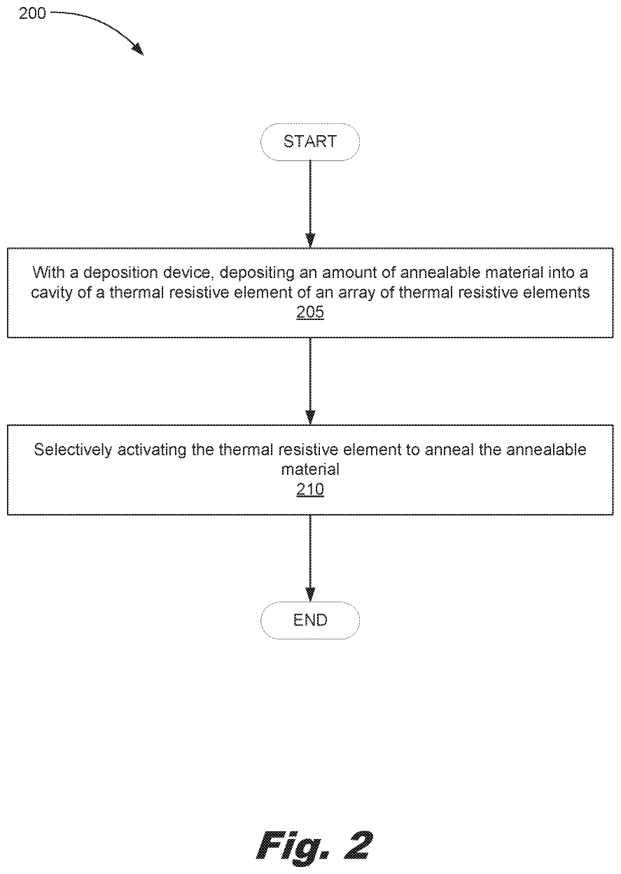

FIG. 2 is a flowchart showing a method (200) of annealing an annealable material according to an example of the principles describe herein. The method (200) may begin with depositing (205) an amount of annealable material into a cavity of a thermal resistive element. The deposition (205) of the annealable material may be accomplished using any type of deposition device. In an example, the deposition device is a printhead that includes a number of thermal ink-jet resistive devices or piezoelectric devices to precisely eject an amount of annealable material through a nozzle and into the cavity.

The cavity may be formed into the body of a thermal resistive element as described herein. In an example, a plurality of cavities may be formed into a plurality of thermal resistive elements arranged into an array of thermal resistive elements. As such, the deposition device may be provided with information as to the layout of the individual thermal resistive elements in the array and, more particularly, the layout of the cavities formed in the thermal resistive elements of the array of thermal resistive elements. In an example, a plurality of cavities maybe formed into a single thermal resistive element. In this example, the annealable material may be selectively deposited into a single or a plurality of the cavities formed into each of the thermal resistive elements.

In the example where the array of thermal resistive elements is arranged in a 2D plane, each of the thermal resistive elements may be selectively activated (210). In any example presented herein, the activation of the thermal resistive elements may be controlled by addressing each individual thermal resistive device. In some examples, the activation of any of the thermal resistive elements may not be dependent on whether or not an annealable material has been deposited (205) into the cavity formed therein. In this example, the activation of each of the thermal resistive elements is not dependent on whether any of the other cavities formed into the any of the other thermal resistive elements receive an annealable material.

When a cavity of any of the thermal resistive elements receives the annealable material, the thermal resistive element may be activated sufficient to raise the temperature of the thermal resistive element so as to anneal the annealable material. The temperature the thermal resistive element is raised to may be dependent on the annealing temperature of the annealable material. In some examples, the annealable material may include semiconducting materials including III-V or II-VI semiconductors, Si, Ge, transition metal dichalcogenides (WS2, WSe2, MoSes, MoS2, etc.), graphene nanoribbons, semiconducting carbon nanotubes, and fullerenes and fullerene derivatives, or combinations thereof. The varying annealing temperatures of these example semiconducting materials may vary and the thermal resistive elements may be provided with an electrical signal sufficient to raise the temperature of the thermal resistive elements and the annealable material to anneal the annealable material.

In some examples, the thermal resistive elements may be heated a number of times in order to form a number of layers of annealed material. In an example, the deposition device may deposit any number of types of annealable material. In these examples, the deposition device may deposit (205) an amount of a first material such as a photoresist and/or a first annealable material. The thermal resistive elements may then be heated in order to cure the photoresist and/or anneal the first layer of annealable material. The deposition device may then deposit another layer of photoresist and/or a second layer of annealable material. Here the thermal resistive elements may again be heated sufficient to cure the second layer of photoresist and/or anneal the second layer of annealable material. In this fashion any location within the array of thermal resistive elements may be selectively activated in order to anneal and/or cure an annealable material and/or photoresist, respectively, any number of times.

In an example, this process may be used to form a number of semiconductors. The layers of the semiconductors may be formed in this way by successively or iteratively depositing an annealable material into the cavities of the thermal resistive elements and annealing the annealable material by activating any of the thermal resistive elements within the array of thermal resistive elements. In any of the examples presented herein, the amount of annealable material or other materials deposited into the cavities of the thermal resistive elements may be equal to or less than the volume capacity of the cavity. The deposition device may therefore be programed to deposit a varying amount of annealable material or other materials as described herein. Therefore, the process and methods (200) described herein may include a plurality of depositions (205) and annealing processes (210) in order to form any type of MEM device such as a semiconductive device.

The method (200) and systems descried herein may also provide for processes that may remove the formed MEM device from the array of thermal resistive elements. In this example, the formed MEM device may be removed by applying a layer of backing material to remove the MEM device from the array of thermal resistive elements. In an example, the thermal resistive elements may be sacrificial elements. In this example, the layers forming the thermal resistive elements may be etched away from the formed MEM device using an acid.

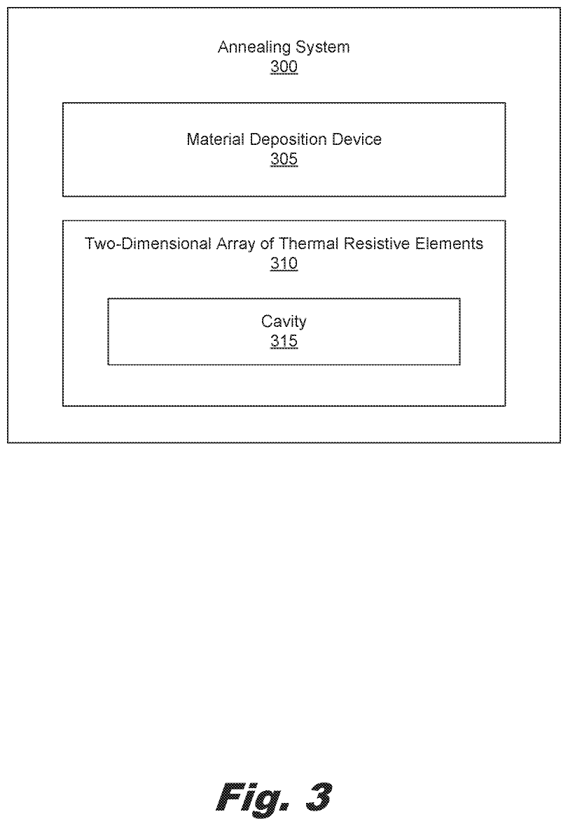

FIG. 3 is a block diagram of an annealing system (300) according to an example of the principles described herein. The annealing system (300) may include a material deposition device (305) and a two-dimensional (2D) array of thermal resistive elements (310).

In any example presented herein, the annealing system (300) may include a processor and a data storage device. The annealing system (300) may be utilized in any data processing scenario including, stand-alone hardware, mobile applications, through a computing network, or combinations thereof. Further, the annealing system (300) may be used in a computing network, a public cloud network, a private cloud network, a hybrid cloud network, other forms of networks, or combinations thereof. In one example, the methods provided by the annealing system (300) are provided as a service over a network by, for example, a third party. The present annealing system (300) may be implemented on multiple hardware platforms, in which the computer readable program code associated with the annealing system (300) may be executed across multiple platforms. Such computer readable program code can run on various forms of cloud technologies and hybrid cloud technologies or offered as a SaaS (Software as a service) that can be implemented on or off the cloud. In another example, the methods provided by the annealing system (300) are executed by a local administrator.

To achieve its desired functionality, the annealing system (300) may include various hardware components. Among these hardware components may be a number of processors a number of data storage devices a number of peripheral device adapters, and a number of network adapters. These hardware components may be interconnected through the use of a number of busses and/or network connections. In one example, the processor, data storage device, peripheral device adapters, and a network adapter may be communicatively coupled via a bus.

The processor may include the hardware architecture to retrieve executable code from the data storage device and execute the executable code. The executable code may, when executed by the processor, cause the processor to implement at least the functionality of with a deposition device, depositing an amount of annealable material into a cavity of a thermal resistive element of an array of thermal resistive elements and selectively activating the thermal resistive element to anneal the annealable material, according to the methods of the present specification described herein. In the course of executing code, the processor may receive input from and provide output to a number of the remaining hardware units.

The data storage device may store data such as executable program code that is executed by the processor or other processing device. As will be discussed, the data storage device may specifically store computer code representing a number of applications that the processor executes to implement at least the functionality described herein. The data storage device may include various types of memory modules, including volatile and nonvolatile memory. For example, the data storage device of the present example includes Random Access Memory (RAM), Read Only Memory (ROM), and Hard Disk Drive (HDD) memory. Many other types of memory may also be utilized, and the present specification contemplates the use of many varying type(s) of memory in the data storage device as may suit a particular application of the principles described herein. In certain examples, different types of memory in the data storage device may be used for different data storage purposes. For example, in certain examples the processor may boot from Read Only Memory (ROM), maintain nonvolatile storage in the Hard Disk Drive (HDD) memory, and execute program code stored in Random Access Memory (RAM).

The hardware adapters in the annealing system (300) enable the processor to interface with various other hardware elements, external and internal to the annealing system (300). For example, the peripheral device adapters may provide an interface to input/output devices, such as, for example, display device, a mouse, or a keyboard. The peripheral device adapters may also provide access to other external devices such as an external storage device, a number of network devices such as, for example, servers, switches, and routers, client devices, other types of computing devices, and combinations thereof.

The material deposition device (305) may be any type of device that may be deposit an amount of, in an example, an annealable material into a cavity (315) formed into each thermal resistive element of the array of thermal resistive elements (310). An example material deposition device (305) may be a TIJ device as described herein. In this example, additional materials may be deposited using the material deposition device (305). These other types of materials may include any materials used to form MEM devices such as a photoresist.

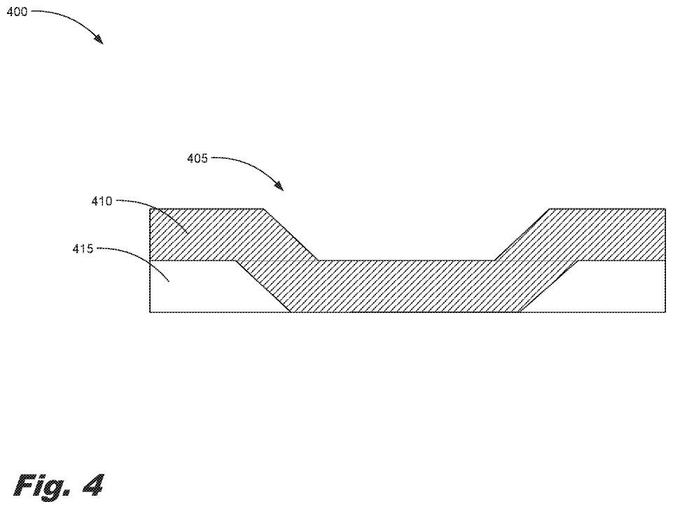

FIG. 4 is a side view of a thermal resistive element (400) according to an example of the principles described herein. As described herein, the thermal resistive element (400) may include a cavity (405) to receive an amount of annealable material therein from a material deposition device (FIG. 3, 305). In any example presented herein, the thermal resistive element (400) may be formed using a layer of high sheet resistivity metal (410) and a layer of relatively low sheet resistivity metal (415). These layers may be etched in any way using any method or substance to form, for example, the cavity (405) therein. In an example, the layer of high sheet resistivity metal (410) may be made of a tungsten silicon nitride (WSiN). In an example, the layer of relatively low sheet resistivity metal (415), may be made of titanium (Ti), a titanium nitride (TiN), and/or aluminum (Al) and copper (Cu) alloys (AlCu). In an example, the center of the cavity (405) may achieve a temperature of 800° Celsius. This temperature may be achieved within a microsecond.

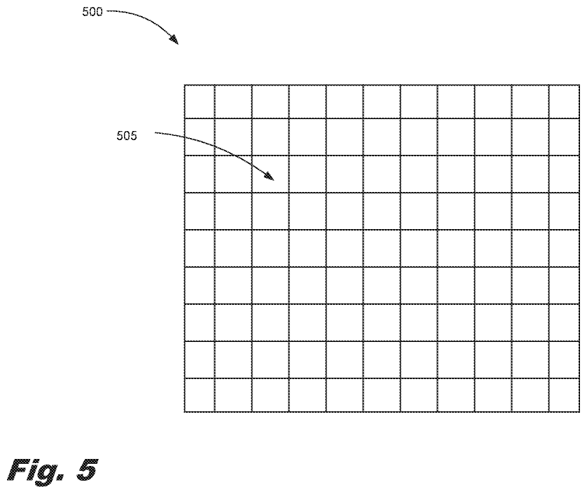

FIG. 5 is a top view of an array of thermal resistive elements (500) according to an example of the principles described herein. FIG. 5 shows an example of an array of thermal resistive elements (500) and is not to be limiting in any particular array of thermal resistive elements as described herein. FIG. 5 shows the selectivity of the individual thermal resistive elements (505) among the array of thermal resistive elements (500). As descried herein, after the deposition of material such as the annealable material described herein, the individual thermal resistive elements (505) may be selectively activated in order to, in an example, anneal the annealable material. This allows the localized activation of any of the thermal resistive elements among the array of thermal resistive elements (500) during any process described in connection with the methods (200) descried herein.

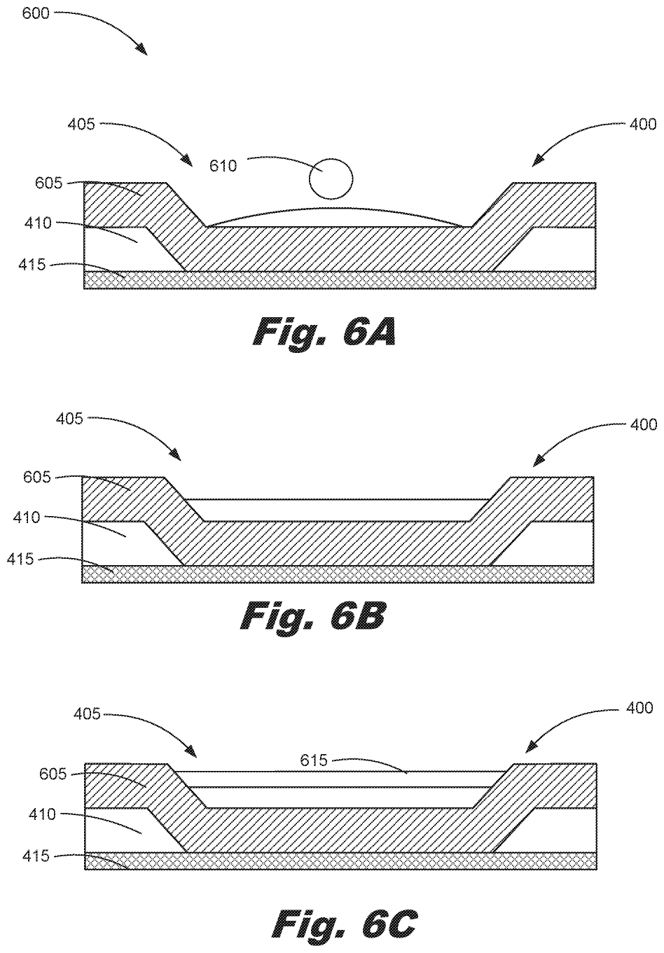

FIGS. 6A-6C are a number of diagrams showing an annealing process (600) according to an example of the principles described herein. FIG. 6A shows the deposition (FIG. 2, 205) of a first annealable material (610) into the cavity (415) of a thermal resistive element (400). As described herein, the first annealable material (610) may be deposited into the cavity (405) of the thermal resistive element (400). In the example show in FIGS. 6A through 6C, the thermal resistive element (400) may further include a passivation layer (605) that prevents the degradation of either the thermal resistive element (400) or the first annealable material (610) during the heating process of the thermal resistive elements (400).

FIG. 6B shows the thermal resistive element (400) after the first annealable material (610) is allowed to settle within the cavity (405) and the first annealable material (610) is being annealed to harden the first annealable material (610). FIG. 6C shows the deposition of a second annealable material (615) on top of the, now annealed, first annealable material (610). As described herein, in an example, the layer of high sheet resistivity metal (410), layer of relatively low sheet resistivity metal (415), and passivation layer (605) may be acid etched away after the first annealable material (610) and second annealable material (615) is annealed.

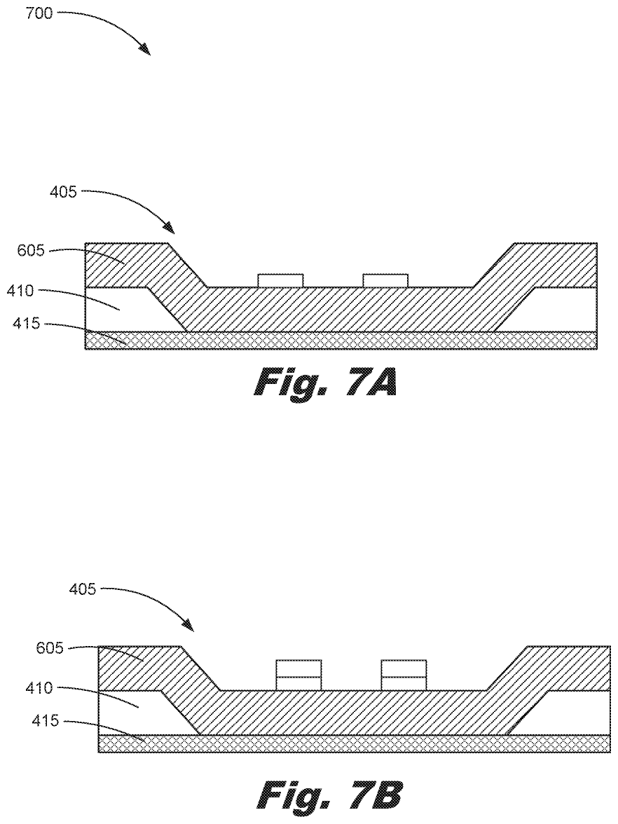

FIGS. 7A and 7B are a number of diagrams showing an annealing process (700) according to an example of the principles described herein. In this example, a photoresist may be presented into the cavity (405) and stamped to provide voids into the photoresist within the cavity (405). The voids formed may serve as a plurality of cavities within the cavity (405) into which the first annealable material (610) and/or second annealable material (615) may be deposited and annealed. After annealing of the first and second annealable materials (610, 615) the photoresist may be washed away. Additionally, the layer of high sheet resistivity metal (410), layer of relatively low sheet resistivity metal (415), and passivation layer (605) may be acid etched away after the first annealable material (610) and second annealable material (615) is annealed.

The specification and figures describe an annealing device and system as well as an annealing process using an array of thermal resistive elements. The use of the thermal resistive elements can reduce the cost of manufacturing MEM devices such as semiconductors. The reduction in costs can be realized in 1) the materials used to form the thermal resistive elements as compared to the use of a CVD or oven and 2) the time used to manufacture the MEM devices as compared with the used of the CVD process or the oven. The use of the thermal resistive elements may further allow for the annealable materials to be built directly onto a chip without transfer of the built devices from a substrate to the chip. Additionally, the building process allows for the selective activation of the thermal resistive elements within the array of thermal resistive elements allowing for additional designable devices to be formed among the thermal resistive elements.

The preceding description has been presented to illustrate and describe examples of the principles described. This description is not intended to be exhaustive or to limit these principles to any precise form disclosed, Many modifications and variations are possible in light of the above teaching.

What is claimed is:

1. An annealing device, comprising:
an array of thermal heaters, each thermal heater comprising a resistive element formed into a cavity; and
wherein each of the thermal heaters within the array of thermal heaters are selectively activated to anneal an annealable material deposited into the cavities.

2. The annealing device of claim 1, wherein the thermal heaters of the array of thermal heaters are arranged in a two-dimensional plane.

3. The annealing device of claim 1, wherein the thermal heaters comprise a layer of resistive metal and a passivation layer.

4. The annealing device of claim 1, further comprising a material deposition device to deposit an amount of annealable material into the cavity.

5. The annealing device of claim 4, where the array of thermal heaters is sacrificial by acid etching revealing an annealed version of the annealable material after selective heating of the thermal heaters.

6. The annealing device of claim 1, wherein the material is heated to an annealing temperature and a layer of polydimethylsiloxane is applied and cured to remove the annealed material from the array of thermal heaters and transfer the annealed material to a substrate.

7. A method of annealing an annealable material, comprising:
with a deposition device, depositing an amount of annealable material into a cavity of a thermal resistive element of an array of thermal resistive elements; and
selectively activating the thermal resistive element to anneal the annealable material.

8. The method of claim 7, comprising iteratively depositing and annealing a plurality of annealable materials in subsequent layers.

9. The method of claim 7, comprising layering the array of thermal resistive elements with a resist and stamping the resist.

10. The method of claim 9, comprising depositing the annealable material over the stamped resist prior to heating the annealable material and washing away the resist to form structured annealed material within the cavity of the thermal resistive element.

11. The method of claim 7, comprising etching away the array of thermal resistive elements after annealing the annealable material.

12. The method of claim 7, comprising depositing a layer of polydimethylsiloxane to the annealed material, curing the polydimethylsiloxane, and removing the annealed material from the array of thermal resistive elements and transferring the annealed material to a substrate.

13. An annealing system, comprising:
a material deposition device to selectively deposit an amount of annealable material; and
a two-dimensional array of thermal resistive elements, each thermal resistive element of the two-dimensional array of thermal resistive elements comprising a cavity to receive an amount of annealable material.

14. The annealing system of claim 13, wherein the thermal resistive elements comprise a first bottom layer of electrically resistive material and a second top passivation layer.

15. The annealing system of claim 13, wherein each of the thermal resistive elements of the two-dimensional array of thermal resistive elements are selectively actuatable to iteratively anneal the annealable material deposited into the cavity.
